(19) United States
(12) Patent Application Publication
(10) Pub. No.: US 2014/0065555 A1
(43) Pub. Date: Mar. 6, 2014

(54) MANUFACTURING METHOD OF SEMICONDUCTOR DEVICE

(71) Applicant: KABUSHIKI KAISHA TOSHIBA, Tokyo (JP)

(72) Inventors: Yasuhito YOSHIMIZU, Mie (JP); Hiroshi TOMITA, Mie (JP); Hisashi OKUCHI, Kanagawa (JP)

(73) Assignee: KABUSHIKI KAISHA TOSHIBA, Tokyo (JP)

(21) Appl. No.: 13/787,281

(22) Filed: Mar. 6, 2013

(30) Foreign Application Priority Data
Aug. 28, 2012 (JP) P2012-187718

(51) Int. Cl. G03F 7/20

(52) U.S. Cl. CPC G03F 7/20
USPC 430/319

(57) ABSTRACT

According to one embodiment, a manufacturing method includes forming a desired pattern containing an uneven pattern on a substrate, subjecting the surface of the desired pattern to a water repellent treatment, forming a resist film on the desired pattern, performing an exposure treatment to expose the uneven pattern, rinsing the substrate with water, and drying the substrate.

### CROSS-REFERENCE TO RELATED APPLICATION

This application is based upon and claims the benefit of priority from Japanese Patent Application No. 2012-187718, filed Aug. 28, 2012; the entire contents of which are incorporated herein by reference.

### FIELD

Embodiments described herein relate to a manufacturing method of a semiconductor device.

### BACKGROUND

There are various kinds of fabrication processes utilized in the manufacturing of semiconductor devices, including a lithography process, an etching process, an ion implantation process, and the like. After each process and before starting the next process, a process of cleaning (washing) and drying are performed to remove impurities and residues on the surface of the wafer, and clean the wafer surface.

For instance, in the cleaning treatment of a wafer after an etching process, a rinse treatment is performed in which a solution for use in the cleaning treatment of the wafer surface is supplied, followed by rinsing in pure water. After the rinsing treatment, a drying treatment is performed in order to remove the pure water remaining on the wafer surface and dry the wafer. During the drying treatment, there is a problem with collapse of the pattern on the wafer due to capillary force. For this reason, a method of using IPA (isopropanol alcohol) has been proposed for drying the wafer in place of using pure water on the wafer. In addition, a method of subjecting the pattern surface to a water repellent treatment using a water repellent that includes an organic solution has also been known.

However, the IPA or water repellent treatments cannot always be used to prevent damage to the pattern formed on the substrate.

### DESCRIPTION OF THE DRAWINGS

FIG. 1-FIG. 4 are cross-sectional views for explaining the manufacturing method of a semiconductor device according to one embodiment.

FIG. 5-FIG. 7 are cross-sectional views for explaining the manufacturing method of the semiconductor device according to a conventional example.

### DETAILED DESCRIPTION

The embodiments described herein provide a manufacturing method that can prevent damage to a pattern on a substrate, more particularly, to a manufacturing method that prevents collapse of an uneven pattern formed by a resist pattern on a semiconductor substrate during a drying treatment after rinsing and development in lithography processes which form the uneven pattern.

In general, according to one embodiment, the manufacturing method of the semiconductor device includes forming a desired pattern containing an uneven pattern on a substrate, subjecting the surface of the desired pattern to a water repellent treatment, forming a resist film on the desired pattern, carrying out an exposure treatment to expose the uneven pattern, rinsing the substrate with water, and drying the substrate.

The present embodiment will be explained based on the figures below.

The cross-sectional views shown in FIG. 1 through FIG. 4 are used to describe the manufacturing method of a semiconductor device according to an embodiment.

First of all, as shown in FIG. 1, a pattern 102 containing a fine uneven pattern 102a (comprised of a plurality of projections and depressions) is formed on a substrate 101. The pattern 102 maybe composed of polysilicon, amorphous silicon, metal, or the like, or it may be composed of a lamination thereof.

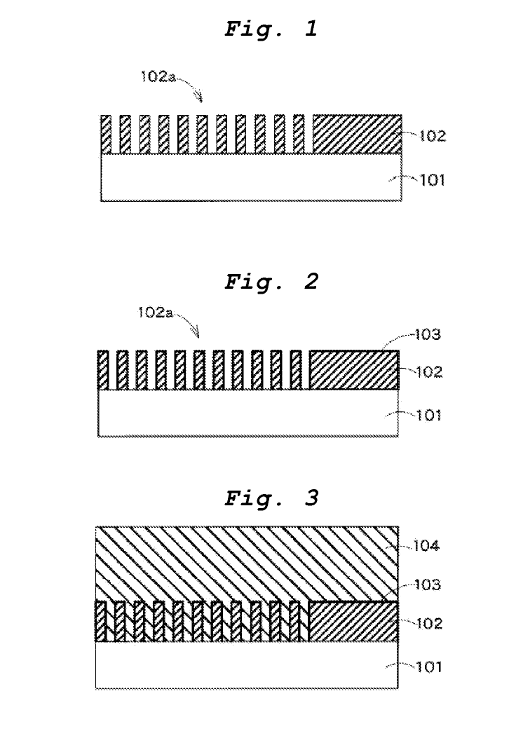

Next, as shown in FIG. 2, water repellent treatment is carried out to the surface of the pattern 102 by coating it with a water repellent material. The water repellent material used here contains carbon, which has resistance to the resist material and solutions to be used in the process later. The carbon-containing material is absorbed on the surface of the pattern 102 to form a carbon-containing film 103.

As the water repellent material, for example, HMDS (hexamethyldisilazane) shown below can be used.

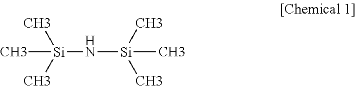

In addition, octadecylsilane shown below having a longer alkyl chain than HMDS may also be used.

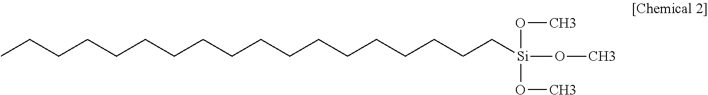 [SMILES: CCCCCCCCCCCCCCCCCC[Si](OC)(OC)OC]

Moreover, in order to control reactivity with the base, thiols and phosphoric acid type can also be used. Octadecanethiol will be shown below as one example of thiols. When the pattern 102 contains precious metal such as Pt or Au, etc., thiols are used for the water repellent material. For example, when the pattern 102 contains Au, alkanethiol is used as the water repellent material.

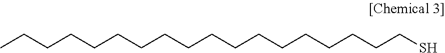 [SMILES: CCCCCCCCCCCCCCCCCCS]

Moreover, octadecane phosphonic acid is shown below as an example of phosphoric acid type.

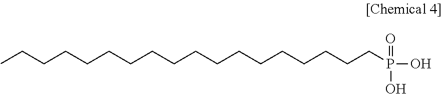 [SMILES: CCCCCCCCCCCCCCCCCCP(=O)(O)O]

The water repellent material may be provided either in liquid or gaseous form, and may form a self-assembled monolayer (SAM) on the surface of the pattern 102. SAM can be formed on the surface of the pattern 102 by, for example, immersing the substrate 101 in an organic solution into which the water repellent material is dissolved, and scattering the organic solution into which the water repellent material is dissolved in a decompression chamber to which the substrate 101 has been introduced. In this case, the water repellent material may have a straight chain alkyl group containing about 8-18 carbon atoms. The reason to set to about 8-18 carbon atoms is because it is easy for the intermolecular force between the straight chain alkyl groups to work with each other and it is suitable to form a self-assembled monolayer.

Moreover, in order to increase the resistance to the resist materials and solutions to be used in the subsequence process, an alkyl fluorine chain may also be used in lieu of an alkyl carbon chain. In this case, a film containing fluorocarbon is formed on the surface of the pattern 102.

Next, as shown in FIG. 3, the substrate 101 and the pattern 102 are coated with a resist 104.

As shown in FIG. 4, the resist 104 is exposed and removed by developing it to form an opening part 105 exposing the carbon-containing film 103 on the portion of the uneven pattern 102a. A mixture of TMAH (tetramethyl ammonium hydroxide) and surfactant is used as a developer, for example. After the development treatment, pure water (de-ionized water (DIW)) is supplied to the substrate 101 to perform a rinsing treatment. After rinsing with pure water, the substrate 101 is dried by spin drying or the like.

Since the water repellent treatment is performed on the surface of the pattern 102, the contact angle of the pure water becomes large during drying. For this reason, the liquid surface tension acting on the uneven pattern 102a becomes smaller during drying treatment, preventing the uneven pattern 102a from collapsing.

Subsequently, the carbon-containing film 103 on the surface of the pattern 102 will be removed during stripping of the resist 104 in a later process.

### COMPARATIVE EXAMPLE

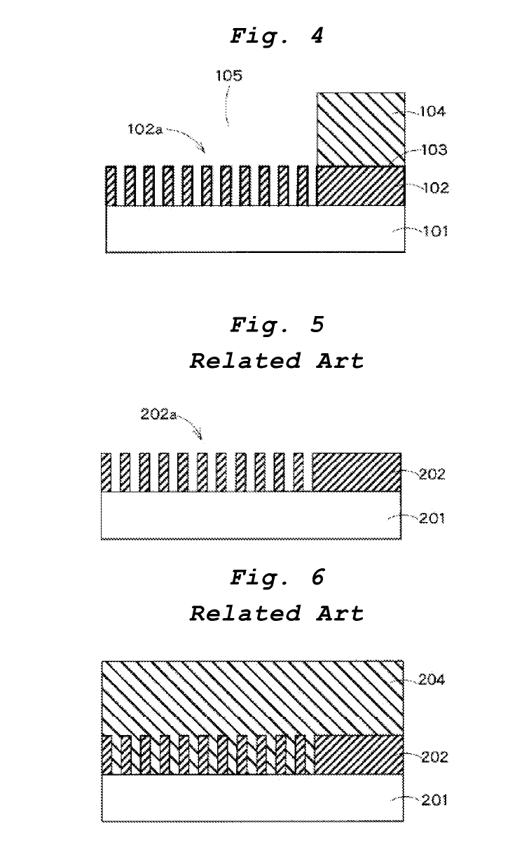

The manufacturing method of the semiconductor device according to a conventional example will be described using FIG. 5 through FIG. 7.

First, as shown in FIG. 5, a pattern 202 containing a fine uneven pattern 202a is formed on the substrate 201. The pattern 202 is composed of polysilicon, amorphous silicon, metal or the like, or it may be composed of a lamination thereof.

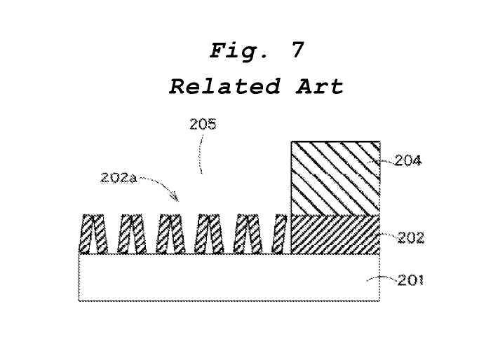

As shown in FIG. 6, the resist 204 is coated on the substrate 201 and the pattern 202.

Next, as shown in FIG. 7, the resist 204 is exposed and developed to form an opening part 205 exposing the portion of the uneven pattern 202a. After the development treatment, pure water is provided to the substrate 201 for carrying out a rinsing treatment. After rinsing with pure water, the substrate 201 is dried by a spin drying or the like. At this time, a large surface tension of the pure water is acting on the uneven pattern 202a, collapsing the uneven pattern 202a.

On the other hand, according to the embodiment described above, water repellent treatment is carried out on the surface of the pattern 102 before resist coating, so the liquid surface tension acting on the uneven pattern 102a becomes small in the drying treatment after carrying out the exposure, development and pure water rinsing, making it possible to, prevent pattern collapse on the uneven pattern 102a. The water repellent material used in the water repellent treatment on the surface of the pattern 102 has resistance to the resist material or the like, making it possible to maintain the water repellent property even after development.

According to the embodiments described herein, the substrate 101 may be rinsed using an organic solvent such as a petroleum type solvent, or the like, after the water repellent treatment, but before coating with the resist 104. In addition, after the rinsing, the organic solvent may be replaced with an IPA, and spin drying may be performed.

Moreover, after the water repellent treatment, baking (heat treatment) of the substrate 101 may also be performed. In this way, the chemical resistance of the carbon-containing film 103 can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method for a semiconductor device, comprising:
forming an uneven pattern above a substrate;
performing a water repellent treatment on a surface of the uneven pattern;
forming a resist film on the uneven pattern;
performing an exposure treatment and a development treatment to expose the uneven pattern;
rinsing the substrate with water; and
drying the substrate.

2. The manufacturing method of the semiconductor device according to claim 1, wherein the water repellent treatment is performed using a water repellent material that comprises carbon.

3. The manufacturing method of the semiconductor device according to claim 2, wherein
the uneven pattern contains a precious metal, and
the water repellent material comprises a thiol.

4. The manufacturing method of the semiconductor device according to claim 3, wherein the thiol is octadecanethiol.

5. The manufacturing method of the semiconductor device according to claim 1, wherein performing the water repellent treatment on the surface of the uneven pattern comprises forming a carbon containing film on the uneven pattern.

6. The manufacturing method of the semiconductor device according to claim 5, wherein the carbon containing film is a self-assembled monolayer.

7. The manufacturing method of the semiconductor device according to claim 6, wherein
the uneven pattern contains a precious metal, and
the carbon containing film comprises a thiol.

8. The manufacturing method of the semiconductor device according to claim 7, wherein the thiol is octadecanethiol.

9. The manufacturing method of the semiconductor device according to claim 1, wherein carbon or fluorocarbon is absorbed on the surface of the uneven pattern during the water repellent treatment.

10. The manufacturing method of the semiconductor device according to claim 9, wherein
the uneven pattern contains a precious metal, and the water repellent material comprises a thiol.

11. The manufacturing method of the semiconductor device according to claim 10, wherein the thiol is octadecanethiol.

12. The manufacturing method of the semiconductor device according to claim 2, wherein
the water repellent treatment is performed using a water repellent material that comprises a straight chain alkyl group containing 8 to 18 carbon atoms.

13. The manufacturing method of the semiconductor device according to claim 12, wherein
the uneven pattern contains a precious metal, and
the water repellent material comprises a thiol.

14. The manufacturing method of the semiconductor device according to claim 13, wherein the thiol is octadecanethiol.

15. The manufacturing method of the semiconductor device according to claim 1, wherein the uneven pattern is exposed to an organic solvent after the water repellent treatment but before forming the resist film.

16. A manufacturing method of a semiconductor device, comprising:
forming a desired pattern of projections and depressions above a substrate;
performing a water repellent treatment on a surface of the desired pattern using a water repellent material that contains carbon;
forming a resist film on the desired pattern;
performing an exposure treatment to expose the projections and depressions;
rinsing the substrate with water; and
drying the substrate.

17. The manufacturing method of the semiconductor device according to claim 16, wherein performing the water repellent treatment comprises forming a carbon containing film on the desired pattern, the carbon containing film comprising a thiol having a straight-chain alkyl group containing 8-18 carbon atoms.

18. The manufacturing method of the semiconductor device according to claim 16, wherein
wherein the uneven pattern contains a precious metal.

19. The manufacturing method of the semiconductor device according to claim 16, wherein and the water repellent material comprises a thiol.

20. The manufacturing method of the semiconductor device according to claim 19, wherein the thiol comprises a straight-chain alkyl group containing 8-18 carbon atoms.
